(19) United States
(12) Patent Application Publication
(10) Pub. No.: US 2011/0073175 A1
(43) Pub. Date: Mar. 31, 2011

(54) PHOTOVOLTAIC CELL COMPRISING A THIN LAMINA HAVING EMITTER FORMED AT LIGHT-FACING AND BACK SURFACES

(75) Inventors: Mohamed M. Hilali, Sunnyvale, CA (US); Christopher J. Petti, Mountain View, CA (US)

(73) Assignee: TWIN CREEKS TECHNOLOGIES, INC., San Jose, CA (US)

(21) Appl. No.: 12/568,940

(22) Filed: Sep. 29, 2009

(51) Int. Cl. H01L 31/00; H01L 31/18

(52) U.S. Cl. 136/256; 438/96; 257/E21.09

(57) ABSTRACT

A photovoltaic cell is described having emitter portions formed at both a light-facing surface and a back surface of the cell. In some embodiments, heavily doped emitter regions extend between the front and back emitter regions, connecting them electrically. Use of this structure is particularly well-adapted to a cell formed by implanting a semiconductor donor body with hydrogen and/or helium ions, affixing the donor body to a receiver element, cleaving a lamina from the donor body, and completing fabrication of a photovoltaic cell comprising the lamina. The emitter portion formed at the unbonded surface may comprise amorphous silicon. The lamina may be thin, for example 10 microns thick or less.

### BACKGROUND OF THE INVENTION

The invention relates to a photovoltaic cell comprising a thin lamina, the photovoltaic cell having emitter regions at both its light-facing surface and its back surface.

Minority charge carriers generated in the base of a photovoltaic cell must reach the emitter of the cell without falling into the valence band of an atom, or recombining, in order to contribute to the cell's photocurrent. Having emitter regions formed at both the light-facing surface and back surface of the cell decreases travel distance required for minority carriers, also decreasing the likelihood of recombination before reaching the collecting junction. Forming a heavily doped emitter region at both the light-facing and back surfaces of a photovoltaic cell may be difficult when certain fabrication techniques are used to form the cell, however.

There is a need, therefore, for a method to form a photovoltaic cell having emitter regions at both light-facing and back surfaces which are compatible with certain fabrication methods.

### SUMMARY OF THE PREFERRED EMBODIMENTS

The present invention is defined by the following claims, and nothing in this section should be taken as a limitation on those claims. In general, the invention is directed to a photovoltaic cell having emitter regions formed at both its light-facing surface and its back surface.

A first aspect of the invention provides for a photovoltaic cell comprising a substantially crystalline semiconductor lamina having a light-facing surface and a back surface; and an emitter, wherein a first portion of the emitter is formed at or in contact with the light-facing surface, and a second portion of the emitter is formed at or in contact with the back surface, and wherein the lamina has a thickness, between the light-facing surface and the back surface, no more than about fifteen microns.

An embodiment of the present invention provides for a photovoltaic cell comprising a substantially crystalline semiconductor lamina having a light-facing surface and a back surface, the semiconductor lamina comprising at least a portion of a base of the photovoltaic cell; and an emitter, the emitter having a first emitter portion formed at or in immediate contact with the light-facing surface, and the emitter having a second emitter portion formed at or in immediate contact with the back surface, wherein either the first emitter portion or the second emitter portion comprises heavily doped amorphous silicon.

Another aspect of the invention provides for a method to fabricate a photovoltaic cell, the method comprising the steps of providing a substantially crystalline semiconductor lamina having a light-facing surface and a back surface; and forming an emitter of the photovoltaic cell, wherein a first portion of the emitter is formed at or in contact with the light-facing surface, and a second portion of the emitter is formed at or in contact with the back surface, and wherein the lamina has a thickness, between the light-facing surface and the back surface, no more than about fifteen microns.

Each of the aspects and embodiments of the invention described herein can be used alone or in combination with one another.

The preferred aspects and embodiments will now be described with reference to the attached drawings.

### BRIEF DESCRIPTION OF THE DRAWINGS

FIG. 1 is a cross-sectional drawing of a prior art photovoltaic cell.

FIGS. 2a-2d are cross-sectional drawings of stages of fabrication of a photovoltaic cell formed according to an embodiment of U.S. patent application Ser. No. 12/026,530.

FIGS. 3a and 3b are cross-sectional views illustrating fabrication of a photovoltaic cell having front and back emitter regions according to an embodiment of the present invention.

FIGS. 4a through 4f are cross-sectional views illustrating stages in fabrication of a photovoltaic cell having front and back emitter regions according to an embodiment of the present invention.

FIG. 5 is a cross-sectional view of an embodiment of the present invention in which the receiver element serves as a superstrate in the completed device.

### DETAILED DESCRIPTION OF THE PREFERRED EMBODIMENTS

A conventional prior art photovoltaic cell includes a p-n diode; an example is shown in FIG. 1. A depletion zone forms at the p-n junction, creating an electric field. Incident photons (incident light is indicated by arrows) will knock electrons from the valence band to the conduction band, creating free electron-hole pairs. Within the electric field at the p-n junction, electrons tend to migrate toward the n region of the diode, while holes migrate toward the p region, resulting in current, called photocurrent. Typically the dopant concentration of one region will be higher than that of the other, so the junction is either a p+/n-junction (as shown in FIG. 1) or a n+/p-junction. The more lightly doped region is known as the base of the photovoltaic cell, while the more heavily doped region is known as the emitter. Most carriers are generated within the base, and it is typically the thickest portion of the cell. The base and emitter together form the active region of the cell. The cell also frequently includes a heavily doped contact region in electrical contact with the base, and of the same conductivity type, to reduce surface recombination and provide a low-resistance contact. In the example shown in FIG. 1, the heavily doped contact region is n-type.

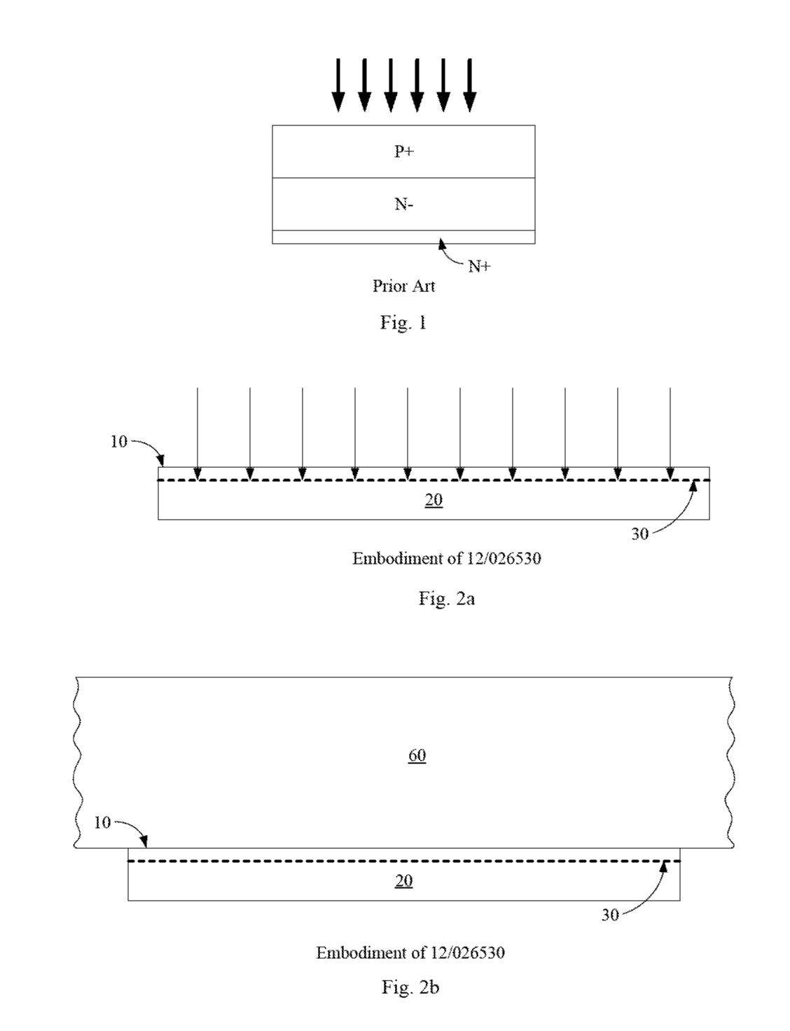

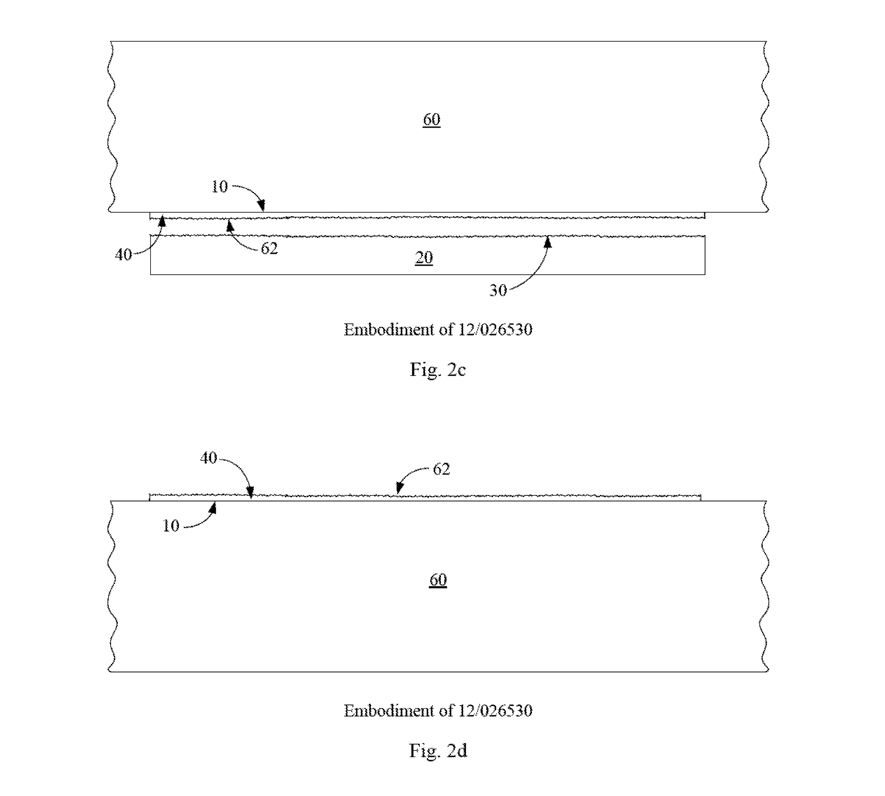

Sivaram et al., U.S. patent application Ser. No. 12/026,530, “Method to Form a Photovoltaic Cell Comprising a Thin Lamina,” filed Feb. 5, 2008, owned by the assignee of the present invention and hereby incorporated by reference, describes fabrication of a photovoltaic cell comprising a thin semiconductor lamina formed of non-deposited semiconductor material. Referring to FIG. 2a, in embodiments of Sivaram et al., a semiconductor donor wafer 20 is implanted through first surface 10 with one or more species of gas ions, for example hydrogen and/or helium ions. The implanted ions define a cleave plane 30 within the semiconductor donor wafer. As shown in FIG. 2b, donor wafer 20 is affixed at first surface 10 to receiver 60. Referring to FIG. 2c, an anneal causes lamina 40 to cleave from donor wafer 20 at cleave plane 30, creating second surface 62. In embodiments of Sivaram et al., additional processing before and after the cleaving step forms a photovoltaic cell comprising semiconductor lamina 40, which is between about 0.2 and about 100 microns thick, for example between about 0.2 and about 50 microns, for example between about 1 and about 20 microns thick, in some embodiments between about 1 and about 10 microns thick or less than about 15 microns thick, though any thickness within the named ranges is possible. FIG. 2d shows the structure inverted, with receiver 60 at the bottom, as during operation in some embodiments. Receiver 60 may be a discrete receiver element having a maximum width no more than 50 percent greater than that of donor wafer 10, and preferably about the same width, as described in Herner, U.S. patent application Ser. No. 12/057,265, “Method to Form a Photovoltaic Cell Comprising a Thin Lamina Bonded to a Discrete Receiver Element,” filed on Mar. 27, 2008, owned by the assignee of the present application and hereby incorporated by reference. Alternatively, a plurality of donor wafers may be affixed to a single, larger receiver, and a lamina cleaved from each donor wafer.

Using the methods of Sivaram et al., photovoltaic cells, rather than being formed from sliced wafers, are formed of thin semiconductor laminae without wasting silicon through excessive kerf loss or by fabrication of an unnecessarily thick cell, thus reducing cost. The same donor wafer can be reused to form multiple laminae, further reducing cost, and may be resold after exfoliation of multiple laminae for some other use.

As noted earlier, a conventional photovoltaic cell includes a p-n junction. Typically the emitter region is heavily doped to a first conductivity type, while the base region is lightly doped to the opposite conductivity type. In a conventional photovoltaic cell, the emitter is often formed at the light-facing surface of the cell. In order to contribute to photocurrent, each minority carrier must travel from its point of generation, generally in the base region of the cell, to the emitter. The greater this distance, the greater the likelihood that the carrier will recombine before it reaches the emitter, and will not contribute to the cell's photocurrent, thus reducing cell efficiency. In the present invention, emitter regions are formed at both the light-facing surface and the back surface of the cell, reducing the travel distance for minority carriers.

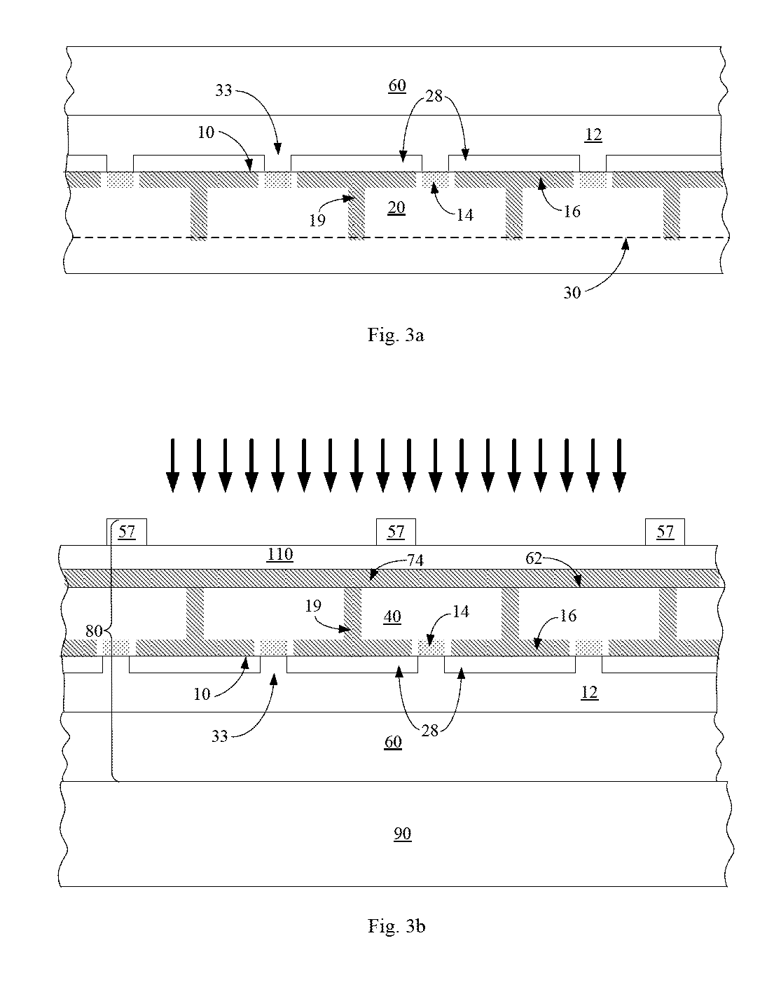

FIG. 3a shows donor wafer 20. Heavily doped emitter region 16 is formed at first surface 10. Emitter region 16 can be either n-type or p-type; in this example it is heavily doped p-type and the body of donor wafer 20 is lightly doped n-type. Heavily doped emitter contacts 19, also p-type, are formed, for example, by a long diffusion step, and extend to nearly the depth of cleave plane 30, or slightly beyond it. Note cleave plane 30 is formed by implant after all high-temperature steps at first surface 10 are complete.

Next, base contact region 14 is formed. This region is heavily doped to the same conductivity type as the base region, and in this example is n-type. A dielectric layer 28 is formed at first surface 10, and conductive layer 12 contacts base contact region 14 in vias 33 formed in dielectric layer 28. In some embodiments, conductive layer 12 will be a stack of conductive materials. Donor wafer 20 is bonded to receiver element 60 with dielectric layer 28 and conductive layer 12 intervening.

Turning to FIG. 3b, which shows the structure inverted with receiver element 60 on the bottom, lamina 40 is cleaved from the donor wafer at the cleave plane. Emitter contact regions 19 are exposed at second surface 62, or can be exposed by removing some small thickness at second surface 62. A first heavily doped emitter region 16 exists at first surface 10, which, in this embodiment, will be the back of the photovoltaic cell. A second heavily doped emitter region is formed at second surface 62, which will be the light-facing surface of the photovoltaic cell, for example by depositing heavily doped amorphous silicon layer 74. In this example, heavily doped amorphous silicon layer 74 is p-type. In the embodiment shown here, heavily doped emitter region 16 at first surface 10 is electrically connected to emitter region 74 by emitter contact regions 19, which extend between them. In other embodiments, different methods could be used to connect these regions. A transparent conductive oxide 110 is formed on heavily doped amorphous silicon layer 74, and wiring 57 completes the cell. Wiring 57 may be formed by any suitable method, including screen printing or ink jet printing. Photovoltaic assembly 80, which includes lamina 40, receiver element 60, and includes a photovoltaic cell, can be mounted on a support substrate 90, or on a superstrate, not shown. In this embodiment, incident light, indicated by arrows, enters lamina 40 at second surface 62.

Aspects of the present invention are well adapted for use in a photovoltaic cell formed by implanting a donor body to define a cleave plane, bonding the donor body to a receiver element, and cleaving a lamina from the donor body at the cleave plane, as described in Sivaram et al., earlier incorporated by reference. The implanted ions cause some damage to the crystal lattice of the lamina. Flaws in the silicon lattice serve as recombination sites, increasing the likelihood that a minority carrier will recombine. Thus, decreasing the distance that minority carriers must travel offers particular advantage for a photovoltaic cell comprising a lamina formed this way, particularly when the lamina includes the base of the photovoltaic cell, where carriers are generated.

Further, receiver element 60 will be exposed to any high-temperature steps that take place following bonding; thus, either receiver element 60 is advantageously formed of a material or materials that can tolerate high temperature, or temperature post-bonding must be kept relatively low. As will be described in more detail, forming the emitter at second surface 62 by depositing heavily doped amorphous silicon layer 74, as opposed to performing a high-temperature step like diffusion doping, allows temperature post-bonding to be kept relatively low.

This fabrication method offers an additional constraint as well: Excessive topography at first surface 10 of the donor wafer may prevent effective bonding to receiver element 60. If two discreet and isolated sets of wiring had to be formed at first surface 10, one contacting heavily doped emitter region 16, which is p-type, and the other contacting heavily doped base contact regions 14, which are n-type, it would be difficult to form these discreet sets of wiring without creating excessive topography at first surface 10. In embodiments of the present invention, electrical contact at first surface 10 is made only to base contacts 14 by conductive layer 12. Contact to heavily doped emitter region 16 is made by contact emitter regions 19, simplifying the requirements for electrical contact at the bonded surface.

To summarize, this photovoltaic cell comprises a substantially crystalline semiconductor lamina having a light-facing surface and a back surface; and an emitter, wherein a first portion of the emitter is formed at or in contact with the light-facing surface, and a second portion of the emitter is formed at or in contact with the back surface. In most embodiments, the lamina has a thickness, between the light-facing surface and the back surface, no more than about fifteen microns, for example ten microns or less. In the example shown, the first portion of the emitter comprises a heavily doped amorphous silicon layer. The first portion of the emitter and the second portion of the emitter are electrically connected by one or more heavily doped regions extending through the lamina from the light-facing surface to the back surface.

For clarity, a detailed example of a photovoltaic assembly including a receiver element and a lamina having thickness between 0.2 and 100 microns, including an emitter region formed at both the light-facing and back surfaces of the lamina, will be provided. For completeness, many materials, conditions, and steps will be described. It will be understood, however, that many of these details can be modified, augmented, or omitted while the results fall within the scope of the invention.

### Example

The process begins with a donor body of an appropriate semiconductor material. An appropriate donor body may be a monocrystalline silicon wafer of any practical thickness, for example from about 200 to about 1000 microns thick. In alternative embodiments, the donor wafer may be thicker; maximum thickness is limited only by practicalities of wafer handling. Alternatively, polycrystalline or multicrystalline silicon may be used, as may microcrystalline silicon, or wafers or ingots of other semiconductor materials, including germanium, silicon germanium, or III-V or II-VI semiconductor compounds such as GaAs, InP, etc., may be used. In this context the term multicrystalline typically refers to semiconductor material having grains that are on the order of a millimeter or larger in size, while polycrystalline semiconductor material has smaller grains, on the order of a thousand angstroms. The grains of microcrystalline semiconductor material are very small, for example 100 angstroms or so. Microcrystalline silicon, for example, may be fully crystalline or may include these microcrystals in an amorphous matrix. Multicrystalline or polycrystalline semiconductors are understood to be completely or substantially crystalline. It will be appreciated by those skilled in the art that a wafer that consists essentially of “monocrystalline silicon” as the term is customarily used will not exclude silicon with occasional flaws or impurities such as conductivity-enhancing dopants.

The process of forming monocrystalline silicon generally results in circular wafers, but the donor body can have other shapes as well. For photovoltaic applications, cylindrical monocrystalline ingots are often machined to an octagonal cross section prior to cutting wafers. Wafers may also be other shapes, such as square. Square wafers have the advantage that, unlike circular or hexagonal wafers, they can be aligned edge-to-edge on a photovoltaic module with minimal unused gaps between them. The diameter or width of the wafer may be any standard or custom size. For simplicity this discussion will describe the use of a monocrystalline silicon wafer as the semiconductor donor body, but it will be understood that donor bodies of other types and materials can be used.

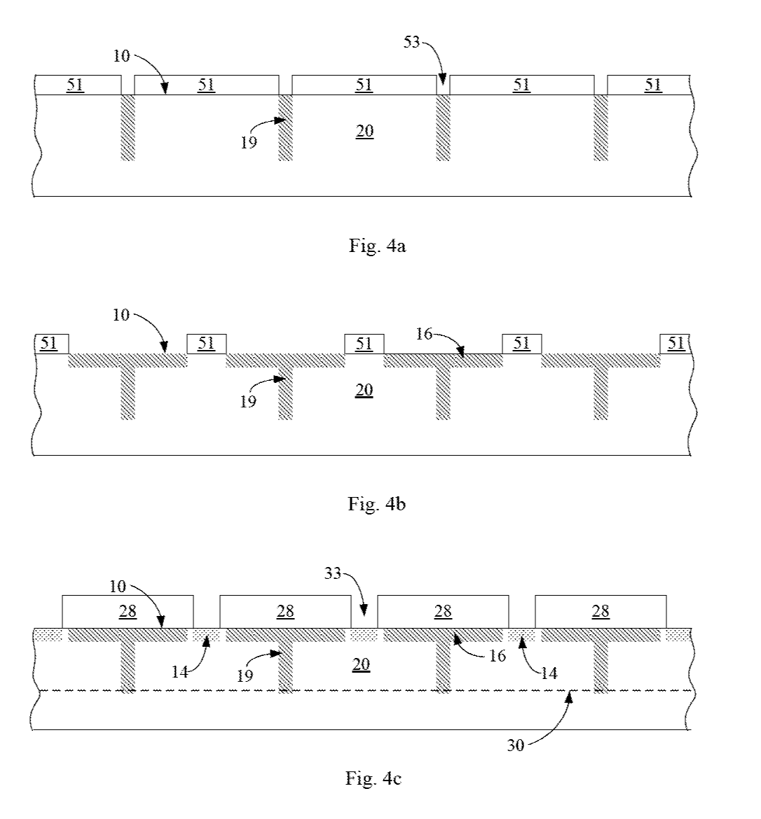

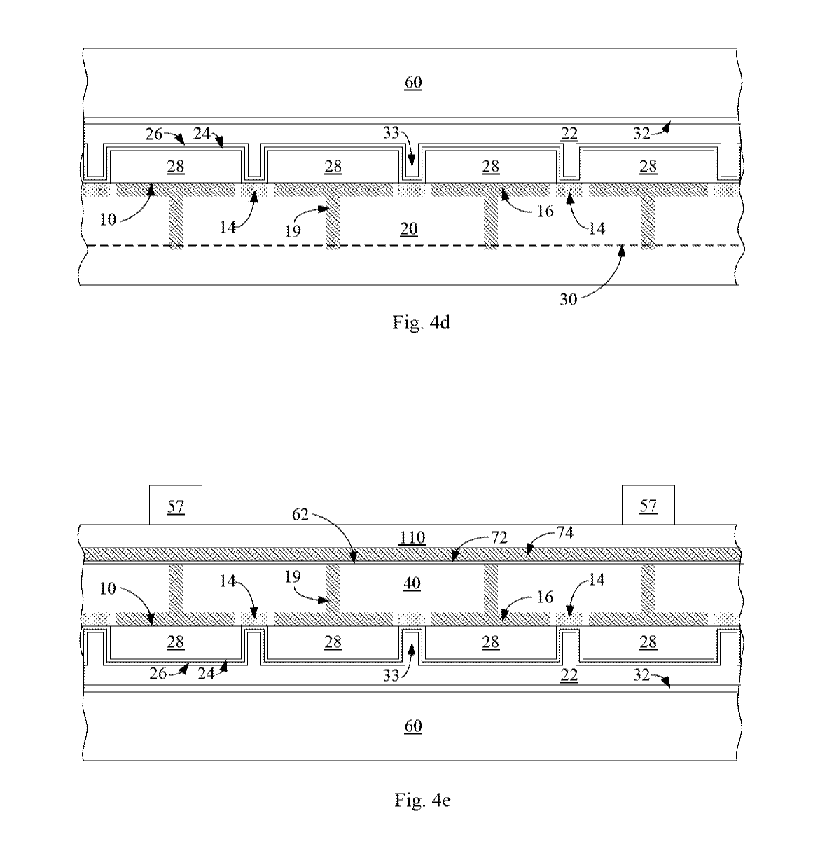

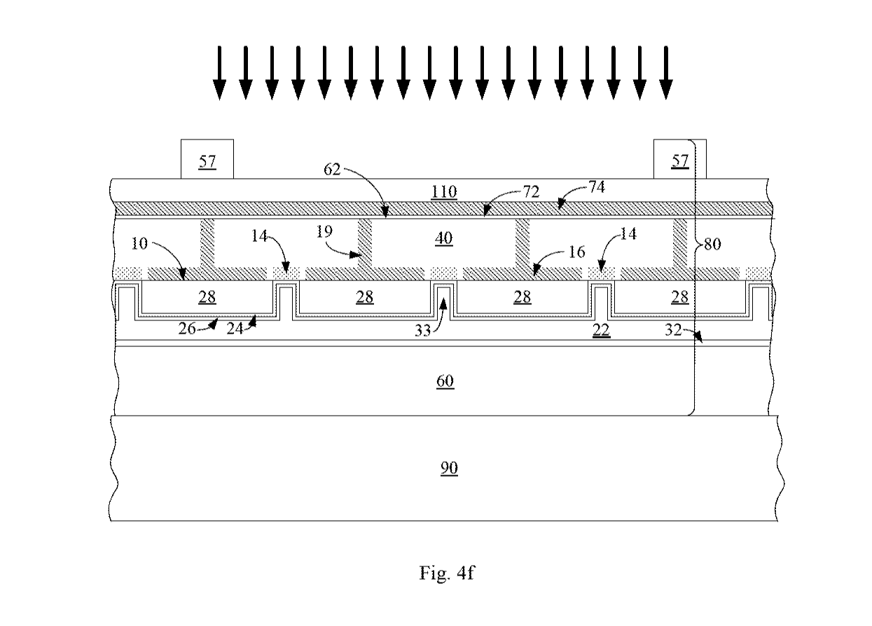

Referring to FIG. 4a, donor wafer 20 is a monocrystalline silicon wafer which is lightly to moderately doped to a first conductivity type. The present example will describe a relatively lightly n-doped wafer 20 but it will be understood that in this and other embodiments the dopant types can be reversed. Wafer 20 may be doped to a concentration of between about 1×10¹⁵ and about 1×10¹⁸ cm⁻³, for example about 1×10¹⁷ cm⁻³. Donor wafer 20 may be, for example, solar- or semiconductor-grade silicon.

First surface 10 of donor wafer 20 may be substantially planar, or may have some preexisting texture. If desired, some texturing or roughening of first surface 10 may be performed, for example by wet etch or plasma treatment. Surface roughness may be random or may be periodic, as described in “Niggeman et al., “Trapping Light in Organic Plastic Solar Cells with Integrated Diffraction Gratings,” Proceedings of the 17^{th} European Photovoltaic Solar Energy Conference, Munich, Germany, 2001. Methods to create surface roughness are described in further detail in Petti, U.S. patent application Ser. No. 12/130,241, “Asymmetric Surface Texturing For Use in a Photovoltaic Cell and Method of Making,” filed May 30, 2008; and in Herner, U.S. patent application Ser. No. 12/343,420, “Method to Texture a Lamina Surface Within a Photovoltaic Cell,” filed Dec. 23, 2008, both owned by the assignee of the present application and both hereby incorporated by reference.

A diffusion barrier layer 51 is deposited or grown at first surface 10. This layer may be, for example, silicon dioxide, and may be 2000 to 2500 angstroms thick or more. Openings 53 are formed in diffusion barrier layer 51. In most embodiments, openings 53 are holes rather than trenches. The size and pitch of openings 53 will be selected depending on a variety of factors, including the doping level of donor wafer 20, the doping level of the heavily doped regions to be formed, the conductive material used to make contact, etc., as will be understood by those skilled in the art. In one embodiment, openings 53 are formed by laser ablation, are circles about 20 microns in diameter, and are formed at a pitch of 1000 microns. FIG. 4a and other drawings are not to scale. A doping step forms heavily doped emitter contact regions 19. Emitter contact regions 19 are doped to the conductivity type opposite the body of donor wafer 20, so in this example emitter contact regions 19 are p-type. Diffusion or any other suitable method may be used to dope emitter contact regions 19 with any p-type dopant, such as boron. Diffusion time and temperature will vary with the dopant and the thickness of the lamina, as is known in the art. This diffusion may be performed in a tube diffusion furnace. Boron, for example, may be diffused at about 1100 degrees C. for about 12.5 hours when the lamina to be produced will have a thickness of about 4.5 microns. If, as in alternative embodiments, donor wafer 20 is p-type, emitter contact regions are doped with an n-type dopant, for example phosphorus. A phosphorus diffusion may be performed between about 850 and about 1150 degrees C. for between about four and about fifteen hours. For example, this anneal may be done at about 1000 degrees C. for a period of about 4 hours and 15 minutes Anneal times may be adjusted for different lamina thicknesses.

In one embodiment, emitter contact regions 19 are doped to a concentration of about 1×10²⁰ cm⁻³, or more, at first surface 10. Dopant concentration will decrease with depth to some degree, but the dopant concentration of emitter contact regions 19 will remain high, for example more than about 5×10¹⁹ cm⁻³ or more, at a depth where a cleave plane will eventually be formed, for example between about 1 and about 10 microns, or between about 1 or 2 and about 5 or 6 microns. A borosilicate glass (not shown) may form at first surface 10 within openings 53 during the doping step.

Next, turning to FIG. 4b, areas of diffusion barrier 51 are stripped from first surface 10, remaining only in patches. This may be done by any suitable method, for example by screen printing an oxide etchant paste, or by screen printing a resist as a mask and etching. In one embodiment these patches 51 are about 300 microns square, and are midway between emitter contact regions 19, though the size, shape, and distribution may be varied as desired.

An additional doping step, which may again be performed by diffusion doping with boron, forms heavily doped p-type emitter region 16 at the newly exposed areas of first surface 10. This doping may be done by any suitable method, for example spraying or spinning borosilicate glass on first surface 10, and, following a drying step, heating to 1000 degrees C. for about 5 minutes. Emitter region 16 may be shallow, for example about 3000 angstroms deep, and may be doped to a concentration between about 10²⁰ and about 10²¹ cm⁻³ or more. Borosilicate glass (not shown) may be formed at first surface 10 in the doped regions.

Diffusion barrier patches 51 are removed, for example, by wet chemical etching in a solution of hydrofluoric acid. This step may remove some or all of a thickness (not shown) of borosilicate glass which may form during the doping step. Turning to FIG. 4c, dielectric layer 28 is deposited or grown on first surface 10. A grown layer provides better passivation. Layer 28 may be part grown and part deposited. In some embodiments this layer will serve both as a diffusion barrier during a doping step, and will also remain in the completed device. This layer may be, for example, silicon dioxide or silicon nitride. If silicon dioxide is used, a suitable thickness may be between about 1500 and 1000 angstroms, while if silicon nitride is used, layer 28 may be, for example, between 1000 and about 1500 angstroms thick. Vias 33 are formed in dielectric layer 28, for example by laser ablation, and expose first surface 10. Vias 33 may be holes rather than trenches, and may have the same pitch as emitter contact regions 19. Any remaining borosilicate glass formed during the doping step to form emitter region 16 is removed where it is exposed in vias 33.

Heavily doped base contact regions 14 are formed by any suitable doping step, for example by diffusion doping. Base contact regions 14 are doped with any n-type dopant, for example phosphorus or arsenic. Dopant concentration may be as desired, for example at least 1×10¹⁸ cm⁻³, for example between about 1×10¹⁸ and 1×10²¹ cm⁻³. A wet etch removes any phosphosilicate glass which may have been formed during this doping step, and also thins dielectric layer 28 slightly. A preferred final thickness for dielectric layer 28 is between about 1000 and 1500 angstroms for silicon dioxide, or between about 700 and 900 angstroms for silicon nitride.

Note that the borosilicate glass formed at first surface 10 has been intentionally removed only where it was exposed in vias 33, though some thickness of it may have been removed during the removal of diffusion barrier patches 51. If any of this glass layer remains, and it is desired to remove it, this removal step can be done before formation of dielectric layer 28.

In the next step, ions, preferably hydrogen or a combination of hydrogen and helium, are implanted through dielectric layer 28 into wafer 20 to define cleave plane 30, as described earlier. The cost of this hydrogen or helium implant may reduced by methods described in Parrill et al., U.S. patent application Ser. No. 12/122,108, “Ion Implanter for Photovoltaic Cell Fabrication,” filed May 16, 2008; or those of Ryding et al., U.S. patent application Ser. No. 12/494,268, “Ion Implantation Apparatus and a Method for Fluid Cooling,” filed Jun. 30, 2009, both owned by the assignee of the present invention and hereby incorporated by reference. The overall depth of cleave plane 30 is determined by several factors, including implant energy. The depth of cleave plane 30 can be between about 0.2 and about 100 microns from first surface 10, for example between about 0.5 and about 20 or about 50 microns, for example between about 1 and about 10 microns or between about 1 or 2 microns and about 5 or 6 microns.

As will be apparent, the depth of cleave plane 30 should be selected so that some portion of heavily doped emitter contact regions 19, doped to an acceptable level for effective electrical contact, will be exposed at the surface of the lamina to be formed following cleaving, or following some treatment of the cleaved surface.

Next a conductive layer or layers should be formed to make electrical contact to base contact regions 14. Turning to FIG. 4d, titanium layer 24 is formed on dielectric layer 28 by any suitable method, for example by sputtering or thermal evaporation. This layer may have any desired thickness, for example between about 20 and about 2000 angstroms, in some embodiments about 300 angstroms thick or less, for example about 100 angstroms. Layer 24 may be titanium or an alloy thereof, for example, an alloy which is at least 90 atomic percent titanium. Titanium layer 24 is in immediate contact with base contact regions 14 at first surface 10 of donor wafer 20 in vias 33; elsewhere it contacts dielectric layer 28.

Non-reactive barrier layer 26 is formed on and in immediate contact with titanium layer 24. This layer is formed by any suitable method, for example by sputtering or thermal evaporation. Non-reactive barrier layer 26 may be any material, or stack of materials, that will not react with silicon, is conductive, and will provide an effective barrier to the low-resistance layer to be formed in a later step. Suitable materials for non-reactive barrier layer include TiW, TiN, W, Ta, TaN, TaSiN, TaO, Ni, or alloys thereof. The thickness of non-reactive barrier layer 26 may range from, for example, between about 100 and about 10,000 angstroms. In some embodiments this layer is about 1000 angstroms thick.

Low-resistance layer 22 is formed on non-reactive barrier layer 26. This layer may be, for example, silver, cobalt, or tungsten or alloys thereof. In this example low-resistance layer 22 is silver or an alloy that is at least 90 atomic percent silver, formed by any suitable method. Silver layer 22 may be between about 5000 and about 100,000 angstroms thick, for example about 20,000 angstroms (2 microns) thick.

In this example, adhesion layer 32 is formed on low-resistance layer 22. Adhesion layer 32 is a material that will adhere to receiver element 60, for example titanium or an alloy of titanium, for example an alloy which is at least 90 atomic percent titanium. In alternative embodiments, adhesion layer 32 can be a suitable dielectric material, such as Kapton or some other polyimide, or, alternatively, a silicate. In some embodiments, adhesion layer 32 is between about 100 and about 5000 angstroms, for example about 400 angstroms.

Next, wafer 20 is affixed to a receiver element 60, with dielectric layer 28, titanium layer 24, non-reactive barrier layer 26, low-resistance layer 22, and adhesion layer 32 intervening. Receiver element 60 may be any suitable material, including glass, such as soda-lime glass or borosilicate glass; a metal or metal alloy such as stainless steel or aluminum; a polymer; or a semiconductor, such as metallurgical grade silicon. The wafer 20, receiver element 60, and intervening layers are bonded by any suitable method, for example by anodic or thermocompression bonding. In some embodiments, receiver element 60 has a widest dimension no more than about twenty percent greater than the widest dimension of wafer 20, and in most embodiments the widest dimension may be about the same as that of wafer 20. In other embodiments, receiver element 60 is significantly larger than wafer 20, and additional donor wafers may be bonded to the same receiver element. Note the stack of materials intervening between receiver element 60 and donor wafer 20 is an example only; other stacks or materials may be used. The stack in this example is described further in Herner, U.S. patent application Ser. No. 12/540,463, “Intermetal Stack For Use in a Photovoltaic Device,” filed Aug. 13, 2009, owned by the assignee of the present application and hereby incorporated by reference.

Referring to FIG. 4e, which shows the structure inverted with receiver element 60 on the bottom, a thermal step causes lamina 40 to cleave from the donor wafer at the cleave plane. In some embodiments, this cleaving step may be combined with a bonding step. Cleaving is achieved in this example by exfoliation, which may be achieved at temperatures between, for example, about 350 and about 650 degrees C., for example between about 450 and 550 degrees C. The thickness of lamina 40 is determined by the depth of cleave plane 30. In many embodiments, the thickness of lamina 40 is between about 1 and about 10 microns, for example between about 1 or 2 and about 5 microns. Bonding and exfoliation may be achieved using methods described in Agarwal et al., U.S. patent application Ser. No. 12/335,479, “Methods of Transferring a Lamina to a Receiver Element,” filed Dec. 15, 2008, owned by the assignee of the present application and hereby incorporated by reference.

Second surface 62 has been created by exfoliation. Second surface 62 will typically have some damage, and steps may be taken to remove or repair this damage. In some embodiments, a KOH or TMAH etch will remove damage and provide some texture.

In other embodiments, damaged silicon is removed at second surface 62, created by exfoliation, by exposing that surface to a selective etch, where the etchant has a significantly higher etch rate for severely damaged silicon than for less-damaged or undamaged silicon. When exposed to this selective etchant, severely damaged silicon will be etched away relatively quickly. When damaged silicon has been removed by this etchant and only lightly damaged silicon remains, the etchant will generally continue to etch the remaining silicon, but more slowly. A variety of etchants having a range of selectivity may be used to remove damaged silicon at second surface 62. In some embodiments, an etchant including acetic acid, hydrofluoric acid, and nitric acid may be used; for example, the etchant may include acetic acid, hydrofluoric acid, and nitric acid in a ratio of 40:1:2. Other components may be included as well. Such a selective etch is described in Clark et al., U.S. patent application Ser. No. 12/484,271, “Selective Etch For Damage Removal at Exfoliated Surface,” filed Jun. 15, 2009, owned by the assignee of the present application and hereby incorporated by reference. An etch step intended to create some texture at this surface to decrease surface reflection and increase light trapping may be combined with the damage-removal etch, or may be performed independently.

In some embodiments, annealing may be performed, for example following the damage-removal etch, to repair implant damage within the body of lamina 40. Annealing may be performed, for example, at 500 degrees C. or greater, for example at 550, 600, 650, 700, 800, 900 degrees C. or greater. In one example, the structure is annealed at about 650 degrees C. for about 45 minutes. In other embodiments, no damage anneal is performed.

In embodiments in which the starting donor wafer is p-type, hydrogen implantation may cause the conductivity type of the resulting lamina 40 to invert, becoming n-type. Performing this anneal at a temperature of 700 degrees C. or above will cause the lamina to invert back to p-type.

During high-temperature steps, such as the damage anneal and the exfoliation of lamina 40, the portions of titanium layer 24 in immediate contact with silicon lamina 40, in vias 33, will react to form titanium silicide.

Still referring to FIG. 4e, if an anneal was performed, an oxide may form on second surface 62 which may be removed by any conventional cleaning step, for example an HF dip. After cleaning, a silicon layer is deposited on second surface 62. This layer 74 includes doped silicon, and may be amorphous, microcrystalline, nanocrystalline, or polycrystalline silicon, or a stack including any combination of these. This layer or stack may have a thickness, for example, between about 100 and about 350 angstroms. FIG. 4c shows an embodiment that includes intrinsic amorphous silicon layer 72 between second surface 62 and doped layer 74. Intrinsic amorphous silicon layer 72 is very thin and does not prevent effective electrical connection between doped layer 74 and emitter contacts 19. In other embodiments, layer 72 may be omitted. In this example, heavily doped silicon layer 74 is doped p-type, opposite the conductivity type of lightly doped n-type lamina 40. Along with emitter region 16 formed at first surface 10 and emitter contact regions 19, which extend through lamina 40, heavily doped amorphous silicon layer 74 serves as the emitter of the photovoltaic cell being formed, while lightly doped n-type lamina 40 comprises the base region. Note that heavily doped amorphous silicon layer 74 has an area equal to more than half of the light-facing surface of lamina 40; indeed in this embodiment equal to nearly the entire light-facing surface of lamina 40.

A transparent conductive oxide (TCO) layer 110 is formed on heavily doped silicon layer 74. Appropriate materials for TCO 110 include indium tin oxide, as well as aluminum-doped zinc oxide, tin oxide, titanium oxide, etc.; this layer may be, for example, about 1000 angstroms thick, and serves as both a top electrode and an antireflective layer. In alternative embodiments, an additional antireflective layer (not shown) may be formed on top of TCO 110.

FIG. 4f shows completed photovoltaic assembly 80, which includes a photovoltaic cell and receiver element 60. The cell includes a base, which is the lightly doped n-type body of lamina 40, and the emitter, which includes heavily doped p-type amorphous or microcrystalline silicon layer 74, heavily doped regions 16, and heavily doped contact regions 19. In many embodiments, emitter region 16 has an area at first surface 10 equal to more than half, or more than 40 percent, of the back surface of lamina 40. Heavily doped n-type regions 14 provide electrical contact to the base region of the cell. Incident light (indicated by arrows) falls on TCO 110, enters the cell at heavily doped p-type microcrystalline silicon layer 74, enters lamina 40 at second surface 62, and travels through lamina 40. In this embodiment, receiver element 60 serves as a substrate. Receiver element 60 may have, for example, a widest dimension about the same as that of lamina 40. Receiver element 60 and lamina 40, and associated layers, form a photovoltaic assembly 80. Multiple photovoltaic assemblies 80 can be formed and affixed to a supporting substrate 90 or, alternatively, a supporting superstrate (not shown).

Electrical contact must be made to both faces of the cell. This contact can be formed using a variety of methods, including those described in Petti et al., U.S. patent application Ser. No. 12/331,376, “Front Connected Photovoltaic Assembly and Associated Methods,” filed Dec. 9, 2008; or Petti et al., U.S. patent application Ser. No. 12/407,064, “Method to Make Electrical Contact to a Bonded Face of a Photovoltaic Cell,” filed Mar. 19, 2009, hereinafter the '064 application, both owned by the assignee of the present application and both hereby incorporated by reference.

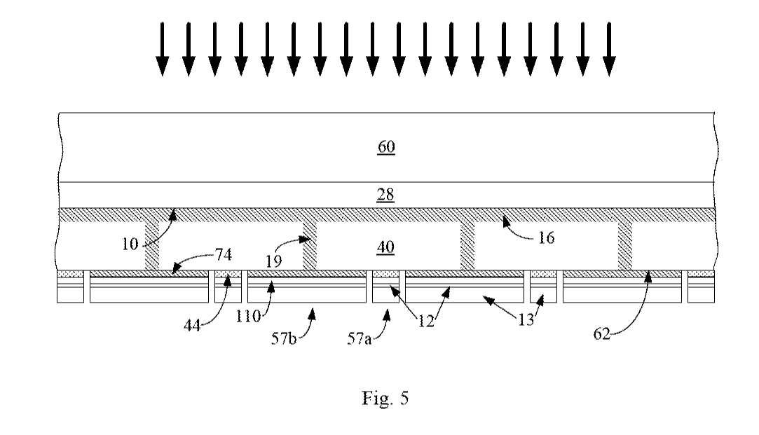

Turning to FIG. 5, in an alternative embodiment, receiver element 60 may serve as a superstrate in the completed cell. One superstrate embodiment, and its fabrication, will be described. In this embodiment, a transparent material 28 such as silicon dioxide or silicon nitride or, alternatively, a TCO, intervene between first surface 10 of lamina 40 and receiver element 60. Receiver element 60 is some transparent material, such as borosilicate glass. In this example the donor wafer is lightly doped n-type. Emitter region 16 is formed at first surface 10, for example by diffusion doping with a p-type dopant, as are emitter contact regions 19. Following bonding of the donor wafer to receiver element 60 and exfoliation of lamina 40 from the donor wafer, emitter regions 74 are formed at second surface 62 of the lamina by deposition of heavily doped p-type amorphous silicon. Layer 74 is patterned, for example by screen printing an etchant paste which will selectively etch amorphous silicon, stopping or slowing on reaching crystalline silicon. Heavily doped n-type amorphous silicon regions are formed at first surface 62, for example using a shadow mask, forming base contact regions 44. A TCO layer 110 is then deposited on emitter regions 74 and base contact regions 44. A seed layer 12, which may be, for example, a very thin nickel layer, is formed by sputtering on TCO 110. Alternatively, the seed layer could be sputtered Ti/TiW/Cu or Al/TiW/Cu. A resist mask is printed, leaving resist in the areas between base contact regions 44 and emitter regions 74. Metal layer or stack 13 is formed, for example by electro-plating. Metal layer or stack 13 may be silver, copper, or some other material or stack of conductive materials. The resist mask is removed and sections of seed layer 12 and TCO layer 110 are etched to isolate wiring elements 57a, which make electrical contact to base contact regions 44, from wiring elements 57b, which make electrical contact to emitter regions 74. This example is provided for completeness only; other embodiments may be formed in which receiver element 60 serves as a superstrate in the completed device.

In other embodiments, a plurality of donor wafers may be affixed to a single receiver element, yielding multiple laminae, which are fabricated into photovoltaic cells as described. The photovoltaic cells may be electrically connected in series, forming a photovoltaic module.

Summarizing, what has been described is a photovoltaic cell comprising a substantially crystalline semiconductor lamina having a light-facing surface and a back surface, the semiconductor lamina comprising at least a portion of a base of the photovoltaic cell; and an emitter, the emitter having a first emitter portion formed at or in immediate contact with the light-facing surface, and the emitter having a second emitter portion formed at or in immediate contact with the back surface, wherein either the first emitter portion or the second emitter portion comprises heavily doped amorphous silicon. Either the first emitter portion or the second emitter portion comprises a heavily doped region of the lamina.

A variety of embodiments has been provided for clarity and completeness. Clearly it is impractical to list all possible embodiments. Other embodiments of the invention will be apparent to one of ordinary skill in the art when informed by the present specification. Detailed methods of fabrication have been described herein, but any other methods that form the same structures can be used while the results fall within the scope of the invention.

The foregoing detailed description has described only a few of the many forms that this invention can take. For this reason, this detailed description is intended by way of illustration, and not by way of limitation. It is only the following claims, including all equivalents, which are intended to define the scope of this invention.

What is claimed is:

1. A photovoltaic cell comprising:
a substantially crystalline semiconductor lamina having a light-facing surface and a back surface; and
an emitter, wherein
a first portion of the emitter is formed at or in contact with the light-facing surface, and
a second portion of the emitter is formed at or in contact with the back surface, and wherein
the lamina has a thickness, between the light-facing surface and the back surface, no more than about fifteen microns.

2. The photovoltaic cell of claim 1 wherein the lamina consists essentially of monocrystalline silicon.

3. The photovoltaic cell of claim 1 wherein the thickness is between about 1 micron and about 10 microns.

4. The photovoltaic cell of claim 1 wherein either the first portion of the emitter or the second portion of the emitter comprises a heavily doped amorphous silicon layer.

5. The photovoltaic cell of claim 1 wherein either the first portion of the emitter or the second portion of the emitter comprises a heavily doped microcrystalline silicon layer.

6. The photovoltaic cell of claim 1 wherein the second portion of the emitter has an area equal to more than half of the back surface of the lamina.

7. The photovoltaic cell of claim 1 wherein the first portion of the emitter has an area equal to more than half of the light-facing surface of the lamina.

8. The photovoltaic cell of claim 1 wherein the first portion of the emitter and the second portion of the emitter are electrically connected by one or more heavily doped regions extending through the lamina from the light-facing surface to the back surface.

9. The photovoltaic cell of claim 1 wherein the lamina is bonded to a receiver element by anodic or thermocompression bonding, with one or more layers disposed between the lamina and the receiver element.

10. The photovoltaic cell of claim 9 wherein the receiver element serves a substrate in the completed device during normal operation.

11. The photovoltaic cell of claim 9 wherein the receiver element serves as a superstrate in the completed device during normal operation.

12. A photovoltaic cell comprising:
a substantially crystalline semiconductor lamina having a light-facing surface and a back surface, the semiconductor lamina comprising at least a portion of a base of the photovoltaic cell; and
an emitter,
the emitter having a first emitter portion formed at or in immediate contact with the light-facing surface, and
the emitter having a second emitter portion formed at or in immediate contact with the back surface, wherein either the first emitter portion or the second emitter portion comprises heavily doped amorphous silicon.

13. The photovoltaic cell of claim 12 wherein the lamina has a thickness, between the light-facing surface and the back surface, no more than about 15 microns.

14. The photovoltaic cell of claim 12 wherein the semiconductor lamina is substantially monocrystalline silicon.

15. The photovoltaic cell of claim 12 wherein the first emitter portion has an area equal to more than half of the light-facing surface of the lamina.

16. The photovoltaic cell of claim 12 wherein the second emitter portion has an area equal to more than half of the back surface of the lamina.

17. The photovoltaic cell of claim 12 wherein the second emitter portion has an area equal to at least 40 percent of the back surface of the lamina.

18. The photovoltaic cell of claim 12 wherein the first emitter portion and the second emitter portion are electrically connected by one or more heavily doped regions extending from the light-facing surface to the back surface of the lamina.

19. The photovoltaic cell of claim 12 wherein either the first emitter portion or the second emitter portion comprises a heavily doped region of the substantially crystalline lamina.

20. A method to fabricate a photovoltaic cell, the method comprising the steps of:
providing a substantially crystalline semiconductor lamina having a light-facing surface and a back surface; and
forming an emitter of the photovoltaic cell, wherein
a first portion of the emitter is formed at or in contact with the light-facing surface, and
a second portion of the emitter is formed at or in contact with the back surface, and wherein
the lamina has a thickness, between the light-facing surface and the back surface, no more than about fifteen microns.

21. The method of claim 20 wherein the lamina consists essentially of monocrystalline silicon.

22. The method of claim 20 wherein either the first portion of the emitter or the second portion of the emitter comprises a heavily doped amorphous silicon layer.
